(19) United States
(12) Patent Application Publication
(10) Pub. No.: US 2023/0397367 A1
(43) Pub. Date: Dec. 7, 2023

(54) LIQUID REPLENISHMENT AND DRAINAGE DEVICE FOR LIQUID-COOLED ENERGY STORAGE SYSTEM AND LIQUID-COOLED ENERGY STORAGE SYSTEM

(71) Applicant: Sungrow Power Supply Co., Ltd., Hefei (CN)

(72) Inventors: Gengjun Hu, Hefei (CN); Meng Zhou, Hefei (CN); Dongdong Fan, Hefei (CN)

(73) Assignee: Sungrow Power Supply Co., Ltd., Hefei (CN)

(21) Appl. No.: 18/169,947

(22) Filed: Feb. 16, 2023

(30) Foreign Application Priority Data
Jun. 2, 2022 (CN) 202221392647.X

(51) Int. Cl. H05K 7/20

(52) U.S. Cl. CPC H05K 7/20272

(57) ABSTRACT

A liquid replenishment and drainage device for a liquid-cooled energy storage system includes a pump, a switching power supply, a first switching valve, a check valve and a pipeline which is configured to be connected to the liquid-cooled energy storage system; the pump is arranged on the first pipeline, and the pump is electrically connected with the switching power supply; two ends of the first switching valve are respectively in communication with the first pipeline, communication positions are respectively located at two ends of the pump, and the check valve is arranged on the first pipeline and is located between the pump and the communication positions. The liquid replenishment and drainage device for the liquid-cooled energy storage system can improve the liquid replenishment and drainage efficiency of the liquid-cooled energy storage system.

### CROSS REFERENCE TO RELATED APPLICATIONS

This application claims the priorities to Chinese patent application No. 202221392647.X, titled “LIQUID REPLENISHMENT AND DRAINAGE DEVICE FOR LIQUID-COOLED ENERGY STORAGE SYSTEM AND LIQUID-COOLED ENERGY STORAGE SYSTEM”, filed with the China National Intellectual Property Administration Jun. 2, 2022, the entire disclosure of which is hereby incorporated by reference.

### FIELD

The present application relates to the technical field of liquid-cooled energy storage systems, in particular to a liquid replenishment and drainage device for a liquid-cooled energy storage system and a liquid-cooled energy storage system.

### BACKGROUND

At present, most of the heat dissipation technologies of an energy storage battery are in the form of forced air cooling, and a small part thereof are in the form of liquid cooling. In a liquid-cooled energy storage system, a coolant is circulable in a pipeline, a liquid-cooled plate and a liquid-cooled unit, and the cold water prepared by a chiller is delivered to the liquid-cooled plate to take away the heat of the battery arranged on the liquid-cooled plate. Compared with an air-cooled energy storage system, the liquid-cooled energy storage system has the advantages of high energy density, low auxiliary power consumption, good temperature uniformity of the battery, etc., and gradually has a trend of replacing the air-cooled energy storage system.

The liquid-cooled energy storage system, however, needs to perform liquid replenishment and liquid drainage in occasions such as after-sales maintenance. In related technologies, the coolant is generally transferred manually, and it is difficult to replenish and drain the liquid.

### SUMMARY

The present application aims to solve the problems of how to improve the liquid replenishment and drainage efficiency of a liquid-cooled energy storage system in the related art to a certain extent.

In order to solve at least one aspect of the above problems to a certain extent, a liquid replenishment and drainage device for a liquid-cooled energy storage system is provided according to a first aspect of the present application, which includes a pump, a switching power supply, a first switching valve, a check valve and a first pipeline which is configured to be connected with the liquid-cooled energy storage system, the pump is arranged on the first pipeline, and the pump is electrically connected with the switching power supply;
two ends of the first switching valve are respectively in communication with the first pipeline, communication positions are respectively located at two ends of the pump, and the check valve is arranged on the first pipeline and is located between the pump and one of the communication positions.

In an embodiment, the liquid replenishment and drainage device for the liquid-cooled energy storage system further includes a pressure detection unit, and the pressure detection unit is arranged at an outlet of the pump.

In an embodiment, the pressure detection unit includes a pressure switch, and the pressure switch is electrically connected with the pump.

In an embodiment, the check valve is located at an inlet of the pump;
or, the check valve is located at the outlet of the pump and is located between the pressure detection unit and the pump.

In an embodiment, the liquid replenishment and drainage device for the liquid-cooled energy storage system further includes a quick-connect connector, one end of the first pipeline is provided with the quick-connect connector, and the quick-connect connector is configured to be connected with the liquid-cooled energy storage system.

In an embodiment, the liquid replenishment and drainage device for the liquid-cooled energy storage system further includes a second switching valve, and the second switching valve is arranged on the first pipeline and is arranged close to the quick-connect connector.

In an embodiment, at least one of the first switching valve and the second switching valve is an electric valve, and the electric valve is electrically connected with the switching power supply.

In an embodiment, the pump is a direct-current self-priming pump.

In an embodiment, the liquid replenishment and drainage device for the liquid-cooled energy storage system further includes a controller, and the controller is electrically connected with the pump, the switching power supply and the first switching valve respectively.

In a second aspect, a liquid-cooled energy storage system is provided according to the present application, which includes the liquid replenishment and drainage device for the liquid-cooled energy storage system in the first aspect.

In the liquid replenishment and drainage device for the liquid-cooled energy storage system and the liquid-cooled energy storage system according to the present application, a working voltage required by the pump is adapted through the switching power supply, the coolant can be driven by the pump to flow into the liquid-cooled energy storage system through the first pipeline when the first switching valve is closed, so as to realize the liquid replenishment of the coolant without manual liquid replenishment. During the liquid replenishment, the check valve can prevent the coolant from flowing back when the pump is abnormal. The pump does not work when the first switching valve is opened, the coolant in the liquid-cooled energy storage system flows out from some pipe sections of the first pipeline and the first switching valve, so as to realize the liquid drainage of the coolant. In addition, the voltage is adjusted through the switching power supply according to the present application, for example, different input voltages are adjusted to the working voltage of the pump, which can ensure the stability of the working voltage of the pump and prevent the working voltage of the pump from being affected by the electric power system of the country or region where the liquid-cooled energy storage system is located, and avoid the risk that the liquid replenishment and drainage device for the liquid-cooled energy storage system cannot be used in countries or regions with different electric power systems, for example, the maintenance personnel such as after-sales service personnel can carry the liquid replenishment and drainage device for the liquid-cooled energy storage system according to the present application to carry out the maintenance of the liquid-cooled energy storage system in countries or regions with different electric power systems. The liquid replenishment and drainage device for the liquid-cooled energy storage system can improve the liquid supplement and drainage efficiency of the liquid-cooled energy storage system, and has strong applicability.

### BRIEF DESCRIPTION OF THE DRAWINGS

FIG. 1 is a schematic structural view of a liquid replenishment and drainage device for a liquid-cooled energy storage system according to an embodiment of the present application;

FIG. 2 is a schematic structural view of the liquid replenishment and drainage device for the liquid-cooled energy storage system according to another embodiment of the present application; and

FIG. 3 is a schematic structural view of the liquid replenishment and drainage device for the liquid-cooled energy storage system according to another embodiment of the present application.

Reference numerals are as follows:

| | |
|---|---|
| 1, pump; | 2, switching power supply; |
| 3, first switching valve; | 4, check valve; |
| 5, first pipeline; | 51, hose; |
| 6, pressure detection unit; | 7, quick-connect connector; |
| 8, second switching valve; | 9, pressure gauge; |
| 10, filter; | 11, liquid inlet. |

### DETAILED DESCRIPTION OF THE EMBODIMENTS

For a better understanding of the objective, technical features and advantages of the present application, specific embodiments of the present application are described in detail in conjunction with drawings.

In a description of the present application, it should be further noted that, unless otherwise explicitly specified and defined, terms such as “installation” and “connection” should be understood in a broad sense, for example, the terms may imply a fixed connection, a detachable connection, or an integral connection; a direct connection or an indirect connection through an intermediate medium. For those skilled in the art, the specific meaning of the above terms in the present application may be understood in the light of specific circumstances.

In the description of the specification, the description with reference to the terms “embodiment”, “an embodiment”, “an implementation manner” means that the specific features, structures, materials or characteristics described in conjunction with the embodiment or implementation are included in at least one embodiment or implementation manner of the present application. In the specification, schematic expressions of the above terms do not necessarily refer to the same embodiments or implementation manners. Furthermore, the specific features, structures, materials or characteristics described may be combined in any one or more embodiments or implementation manners in an appropriate way.

The terms “first” and “second” are only used for descriptive purposes, and should not be construed as indicating or implying relative importance or implicitly indicating the number of technical features referred to. Therefore, the features defined with “first”, “second” or the like may include at least one of the features explicitly or implicitly.

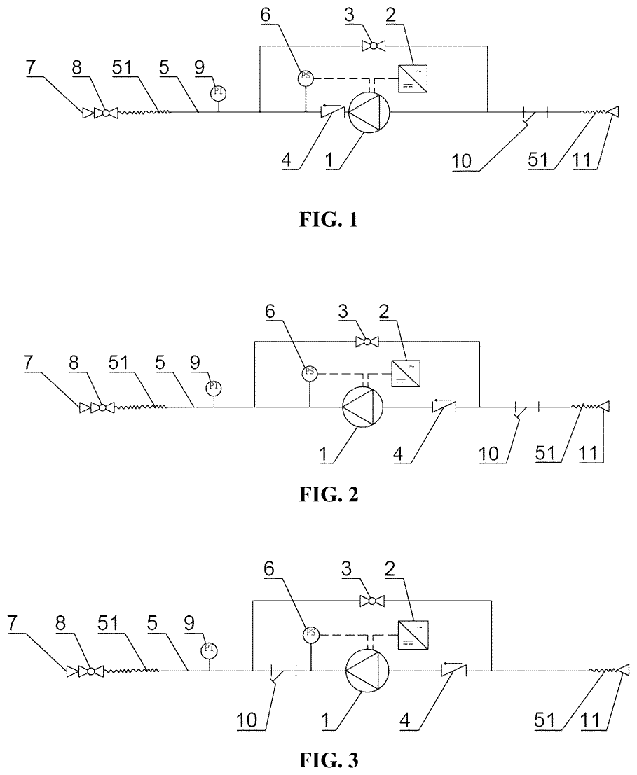

As shown in FIGS. 1 to 3, a liquid replenishment and drainage device for a liquid-cooled energy storage system is provided according to an embodiment of the present application, which includes a pump 1, a switching power supply 2, a first switching valve 3, a check valve 4 and a first pipeline 5 which is configured to be connected with the liquid-cooled energy storage system; the pump 1 is arranged on the first pipeline 5, and the pump 1 is electrically connected with the switching power supply 2;
two ends of the first switching valve 3 are respectively in communication with the first pipeline 5, communication positions are respectively located at two ends of the pump 1, and the check valve 4 is arranged on the first pipeline 5 and is located between the pump 1 and one of the communication positions.

The first pipeline 5 can be understood as a passage through which the coolant flows into the liquid-cooled energy storage system. One end of the first pipeline 5 can be connected with a liquid replenishment port of the liquid-cooled energy storage system, and the other end of the first pipeline 5 is connected with a source of the coolant, such as a liquid tank, through a liquid inlet 11. In actual use, in order to connect components such as the pump 1 or the check valve 4, the first pipeline 5 can be understood as a collection of multiple pipe sections, which is not described in detail later.

The switching power supply 2 can convert different input voltages into the working voltage of the pump 1, which can adopt relevant technologies and is not described in detail herein.

In this way, in the liquid replenishment and drainage device for the liquid-cooled energy storage system and the liquid-cooled energy storage system according to the present application, the working voltage required by the pump 1 is adapted through the switching power supply 2, the coolant can be driven by the pump 1 to flow into the liquid-cooled energy storage system through the first pipeline 5 when the first switching valve 3 is closed, so as to realize the liquid replenishment of the coolant without manual liquid replenishment. During the liquid replenishment, the check valve 4 can prevent the coolant from flowing back when the pump 1 is abnormal. The pump 1 does not work when the first switching valve 3 is opened, the coolant in the liquid-cooled energy storage system flows out from some pipe sections of the first pipeline 5 and the first switching valve 3, so as to realize the liquid drainage of the coolant. In addition, the voltage is adjusted through the switching power supply 2 according to the present application, for example, different input voltages are adjusted to the working voltage of the pump 1, which can ensure the stability of the working voltage of the pump 1 and prevent the working voltage of the pump from being affected by the electric power system of the country or region where the liquid-cooled energy storage system is located, and avoid the risk that the liquid replenishment and drainage device for the liquid-cooled energy storage system cannot be used in countries or regions with different electric power systems, for example, the maintenance personnel such as after-sales service personnel can carry the liquid replenishment and drainage device for the liquid-cooled energy storage system according to the present application to carry out the maintenance of the liquid-cooled energy storage system in countries or regions with different electric power systems. The liquid replenishment and drainage device for the liquid-cooled energy storage system can improve the liquid supplement and drainage efficiency of the liquid-cooled energy storage system, and has strong applicability.

In an optional embodiment of the present application, the liquid replenishment and drainage device for the liquid-cooled energy storage system further includes a pressure detection unit 6, and the pressure detection unit 6 is arranged at an outlet of the pump 1.

As an example, the pressure detection unit 6 includes a digital display pressure sensor, which can detect a pressure value at the outlet end of the pump 1, and the pressure detection unit 6 can further include a digital display flow sensor.

In addition, it should be noted that the pressure detection unit 6 can be integrated on the pump 1 (for example, the pump 1 provided with the pressure detection unit 6), or be arranged outside the pump 1.

In this way, the pressure value of the coolant at the outlet of the pump 1 can be detected by the pressure detection unit 6, the working of the pump 1 can be stopped when the pressure value of the coolant reaches a preset value, and the check valve 4 prevents the coolant from flowing back, so as to protect the pipeline and the pump 1.

Further, the pressure detection unit 6 includes a pressure switch, and the pressure switch is electrically connected with the pump 1.

The pressure switch is generally arranged on a power supply circuit of the pump 1, and the pump 1 stops working when the pressure switch is disconnected.

In this way, a protect value of the pressure at the outlet of the pump 1 can be set, and the pump 1 stops working when the pressure of the coolant reaches the protect value and the pressure switch is disconnected, which can realize the overpressure protection.

Further, the check valve 4 is located at an inlet (referring to FIG. 2) of the pump 1.

Alternatively, the check valve 4 is located at the outlet of the pump 1, and is located between the pressure detection unit 6 and the pump 1 (referring to FIG. 1).

In this way, the coolant can be prevented from flowing back, and the pressure change of the coolant can be detected by the pressure detection unit 6 after the pump 1 stops working.

On this basis, a pressure gauge 9 can be arranged on the first pipeline 5, which facilitates the user to observe the pressure of the coolant.

Referring to FIG. 1, the liquid replenishment and drainage device for the liquid-cooled energy storage system further includes a quick-connect connector 7, one end of the first pipeline 5 is provided with the quick-connect connector 7, and the quick-connect connector 7 is configured to be connected with the liquid-cooled energy storage system.

At this time, the quick-connect connector 7 is located at an end of the first pipeline 5 in an outlet direction of the pump 1. Relevant prior art can be adopted for the quick-connect connector 7, which is adapted to the connector on the liquid-cooled energy storage system, such as the liquid replenishment port. For example, the quick-connect connector 7 is a press-type connector.

In this way, the liquid replenishment and drainage device for the liquid-cooled energy storage system can be quickly connected with the liquid-cooled energy storage system through the quick-connect connector 7, so as to improve the operation efficiency.

Referring to FIG. 1, in an embodiment, the liquid replenishment and drainage device for the liquid-cooled energy storage system further includes a second switching valve 8, which is arranged on the first pipeline 5 and is arranged close to the quick-connect connector 7.

When needed, for example, the pump 1 or the first switching valve 3 is abnormal, the second switching valve 8 can quickly and integrally cut off the first pipeline 5 and the first switching valve 3 at a position close to the liquid-cooled energy storage system (that is, at the quick-connect connector 7), so as to prevent the cooling oil from flowing into or flowing out of the liquid-cooled energy storage system.

Further, at least one of the first switching valve 3 and the second switching valve 8 is an electric valve, and the electric valve is electrically connected with the switching power supply 2.

Taking the first switching valve 3 as an example, the first switching valve 3 is a valve with two states of open and closed, but it can also have other states. For example, it may be arranged as a regulating valve with two states of open and closed and an adjustable opening at a valve port, for example, the first switching valve 3 may be arranged as an electric ball valve, which is not described in detail herein.

The action of the first switching valve 3 and subsequent similar electric valves can be controlled manually or by a controller later on, which is not described in detail herein.

In this way, at least one of the first switching valve 3 and the second switching valve 8 is an electric valve and is energized by the switching power supply 2, which can reduce the workload of maintenance personnel.

In the above embodiments, optionally, the liquid replenishment and drainage device for the liquid-cooled energy storage system further includes a controller, which is electrically connected with the pump 1, the switching power supply 2 and the first switching valve 3 respectively.

The controller can be electrically connected with the second switching valve 8 and the pressure detection unit 6.

In this way, the linkage control between devices can be realized through the controller. For example, during first usage, when the first switching valve 3 is in the open state, the controller can control the pump 1 to be in a non-working state, and when the first switching valve 3 is in the closed state, the controller can control the pump 1 to work.

In addition, when the detection pressure of the pressure detection unit 6 exceeds a safety pressure, the controller can control the pump 1 to stop working, and the controller can control the first switching valve 3 to open, so as to realize pressure relief. For example, the control of the pump 1 fails to stop working, the controller can control the first switching valve 3 to open, so as to ensure the safety use.

In the above embodiments, optionally, the pump 1 is a direct-current self-priming pump.

In this way, the pump 1 has a small volume and a high safety, which does not need to add water every time it is used.

It should be noted that the liquid replenishment and drainage device for the liquid-cooled energy storage system can further include other components such as a filter 10 (referring to FIG. 2 and FIG. 3), and the filter 10 is arranged on the first pipeline 5.

In addition, some pipe sections of the first pipeline 5 can be arranged as a hose 51, which are not limited.

Referring to FIG. 1, the usage method of the liquid replenishment and drainage device for the liquid-cooled energy storage system is illustrated as follows:
when liquid replenishment is required, the quick-connect connector 7 is connected with the liquid-cooled energy storage system, the first switching valve 3 is closed, the second switching valve 8 is opened, and the coolant flows into the liquid-cooled energy storage system through the liquid inlet 11, the filter 10, the check valve 4, the pump 1, the second switching valve 8 and the quick-connect connector 7.

When liquid drainage is required, the first switching valve 3 is closed, the second switching valve 8 is opened, and the coolant in the liquid-cooled energy storage system flows out through the quick-connect connector 7, the first switching valve 3, the filter 10 and the liquid inlet 11.

The liquid-cooled energy storage system according to the present application includes the liquid replenishment and drainage device for the liquid-cooled energy storage system.

The liquid-cooled energy storage system has all the beneficial effects of the liquid replenishment and drainage device for the liquid-cooled energy storage system, which is not described in detail herein.

Although the present application is disclosed as above, the protection scope of the present application is not limited thereto. Those skilled in the art can make various changes and modifications without departing from the spirit and scope of the present application, and these changes and modifications will all fall within the protection scope of the present application.

1. A liquid replenishment and drainage device for a liquid-cooled energy storage system, comprising a pump, a switching power supply, a first switching valve, a check valve and a first pipeline which is configured to be connected with the liquid-cooled energy storage system; wherein the pump is arranged on the first pipeline, and the pump is electrically connected with the switching power supply;
two ends of the first switching valve are respectively in communication with the first pipeline, communication positions are respectively located at two ends of the pump, and the check valve is arranged on the first pipeline and is located between the pump and one of the communication positions.

2. The liquid replenishment and drainage device for the liquid-cooled energy storage system according to claim 1, further comprising a pressure detection unit, wherein the pressure detection unit is arranged at an outlet of the pump.

3. The liquid replenishment and drainage device for the liquid-cooled energy storage system according to claim 2, wherein the pressure detection unit comprises a pressure switch, and the pressure switch is electrically connected with the pump.

4. The liquid replenishment and drainage device for the liquid-cooled energy storage system according to claim 3, wherein the check valve is located at an inlet of the pump;
or, the check valve is located at the outlet of the pump and is located between the pressure detection unit and the pump.

5. The liquid replenishment and drainage device for the liquid-cooled energy storage system according to claim 1, further comprising a quick-connect connector, wherein one end of the first pipeline is provided with the quick-connect connector, and the quick-connect connector is configured to be connected with the liquid-cooled energy storage system.

6. The liquid replenishment and drainage device for the liquid-cooled energy storage system according to claim 5, further comprising a second switching valve, wherein the second switching valve is arranged on the first pipeline and is arranged close to the quick-connect connector.

7. The liquid replenishment and drainage device for the liquid-cooled energy storage system according to claim 6, wherein at least one of the first switching valve and the second switching valve is an electric valve, and the electric valve is electrically connected with the switching power supply.

8. The liquid replenishment and drainage device for the liquid-cooled energy storage system according to claim 1, wherein the pump is a direct-current self-priming pump.

9. The liquid replenishment and drainage device for the liquid-cooled energy storage system according to claim 1, further comprising a controller, wherein the controller is electrically connected with the pump, the switching power supply and the first switching valve.

10. A liquid-cooled energy storage system, comprising the liquid replenishment and drainage device for the liquid-cooled energy storage system according to claim 1.
